(19) United States
(12) Patent Application Publication
(10) Pub. No.: US 2005/0184303 A1
(43) Pub. Date: Aug. 25, 2005

(54) Strain compensating structure to reduce oxide-induced defects in semiconductor devices

(76) Inventors: Ashish Tandon, Sunnyvale, CA (US); Michael Howard Leary, Mountain View, CA (US); Michael Renne Ty Tan, Menlo Park, CA (US); Ying-Lan Chang, Cupertino, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/786,800

(22) Filed: Feb. 25, 2004

(51) Int. Cl. H01S 5/00; H01L 29/22

(52) U.S. Cl. 257/98

(57) ABSTRACT

A strain compensating structure comprises a strain compensating layer adjacent an oxide-forming layer. The strain compensating layer compensates for the change in the lattice parameter due to oxidation of at least part of the oxide-forming layer.

### BACKGROUND OF THE INVENTION

Many semiconductor-based devices, such as application specific integrated circuits (ASICs), transistors, and light emitting devices, such as lasers, employ an oxidized material layer as part of their structure. For example, a vertical cavity surface emitting laser (VCSEL) may include an oxidized semiconductor layer to provide optical and/or electrical current confinement. An ASIC may include an oxidized layer to provide electrical isolation within the device.

A semiconductor-based light emitting device, such as a VCSEL, is formed by epitaxially growing semiconductor material layers over a substrate. In a VCSEL, an oxide layer may be formed by oxidizing a semiconductor material layer that includes a significant amount of an element that is readily oxidized. For example, aluminum (Al) is an element that is frequently added to a semiconductor material layer to promote oxidation of the aluminum-containing layer. Generally, to form an aluminum oxide layer, an aluminum-containing semiconductor layer is grown, and then heated in an oxidizing atmosphere, such as an atmosphere with a high water vapor content. The oxidizing atmosphere oxidizes the exposed areas of any material having a significant aluminum content.

When the aluminum-containing layer is initially grown as a semiconductor material layer, it will generally be grown either lattice matched or pseudomorphically with respect to the substrate on which the layer is grown. In the context of epitaxial semiconductor material layer growth, pseudomorphic growth refers to a semiconductor material layer that is strained, either compressively or in tension, so that its lattice parameter conforms to the lattice parameter of the substrate material. Regardless of whether the aluminum-containing layer is grown lattice matched to the substrate or grown pseudomorphically, the lattice parameter of the aluminum-containing layer will change after the layer is oxidized. Unfortunately, this change in the lattice parameter of the aluminum-containing layer after oxidation causes the layer to become strained with respect to the substrate and adjacent layers. Strain occurs because of a difference in the lattice parameter between semiconductor layers. The strain causes point defects and other lattice deformations to form in the oxidized layer. These defects can migrate into the crystal structure. For example, in the case of a VCSEL, the defects caused by strain in the oxidized layer can migrate into the material layers that form the active region of the VCSEL, thus degrading the optical performance of the VCSEL. Further, these defects migrate at a faster rate when the light-emitting device is electrically biased, as in the case of a VCSEL.

Therefore, it would be desirable to reduce defects caused when a semiconductor layer is oxidized.

### SUMMARY OF THE INVENTION

The invention provides a strain compensating structure for an oxidized semiconductor layer. The strain compensating structure comprises a strain compensating layer adjacent an oxide-forming layer. The strain compensating layer compensates for the change in the lattice parameter due to oxidation of at least part of the oxide-forming layer.

The invention also provides a light-emitting device that comprises an active region configured to generate light in response to injected charge and a current confinement structure located to direct charge into the active region. The current confinement structure includes a strain compensating layer adjacent an oxide-forming layer.

The invention additionally provides a method of making a strain compensating structure comprising providing a substrate, forming over the substrate a strain compensating layer of a first semiconductor material, forming over the substrate an oxide-forming layer of a second semiconductor material juxtaposed with the strain compensating layer, and oxidizing at least part of the oxide-forming layer.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic side view of a strain compensating structure.

FIG. 2 is a schematic side view of a vertical-cavity surface-emitting laser according to the invention.

FIG. 3 is a flow chart illustrating a method according to the invention for making a strain compensating structure.

FIG. 4 is a flow chart illustrating a method according to the invention for generating light.

### DETAILED DESCRIPTION OF THE INVENTION

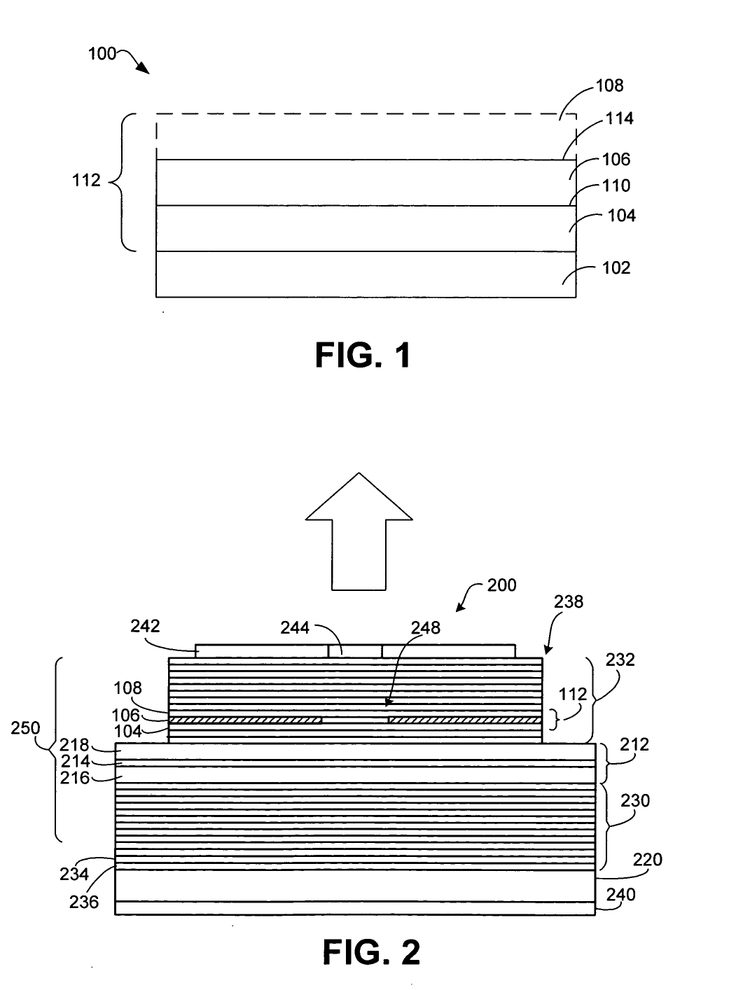

FIG. 1 shows a side view of an example of a semiconductor device 100 incorporating a strain compensating structure 112. The strain compensating structure 112 is composed of a strain compensating layer 104 and an oxide-forming layer 106 adjacent the strain compensating layer 104 and formed over a substrate 102. The strain compensating structure 112 may optionally include an additional strain compensating layer 108 adjacent the oxide-forming layer 106. Many different semiconductor materials can be used to form the strain compensating layer 104 and the oxide-forming layer 106. In the semiconductor device 100 illustrated in FIG. 1, the semiconductor material of the substrate 102 is gallium arsenide (GaAs), the semiconductor material of the strain compensating layer 104 is gallium indium phosphide (GaInP) and the semiconductor material of the oxide-forming layer 106 is aluminum gallium arsenide (AlGaAs) having a high aluminum fraction. The thickness of the layers 104 and 106 should be sufficiently small so that the critical thickness is not exceeded. The critical thickness is the thickness at which crystal defects begin to form due to a mismatch in the lattice parameters of the materials.

The strain compensating layer 104 is formed having a lattice mismatch, i.e., strained either in compression or in tension, with respect to the substrate 102 and the oxide-forming layer 106. The lattice mismatch in the strain compensating layer 104 compensates for the strain that will be induced as a result of the change in the lattice parameter resulting from oxidation of at least part of the oxide-forming layer 106. By carefully choosing the composition of the material of the strain compensating layer 104, the final strain in the completed semiconductor device 100 can be designed to minimize defects caused by oxidation of at least part of the oxide-forming layer 106. For example, the strain compensating layer 104 can be formed either in compression or tension to compensate for strain induced in the device 100 by oxidation of at least part of the oxide-forming layer 106.

A strain compensating layer 104 formed of GaInP with 48% indium and 52% gallium on the group III sub-lattice is lattice matched to the GaAs substrate 102. If the amount of indium in the strain compensating layer 104 is increased to, for example, about 50%, and the amount of gallium is decreased to, for example, about 50%, then the lattice constant of the GaInP becomes larger than that of GaAs substrate. This composition places a strain compensating layer 104 having 50% indium under compressive strain. Similarly, a strain compensating layer 104 having a gallium fraction of, for example, greater than about 52%, and an indium fraction of, for example, less than about 48%, grown on a GaAs substrate will be placed under tensile strain. By controlling the relative amounts of indium and gallium that form the GaInP strain compensating layer 104, the type and degree of strain is controlled. In this manner, strain caused by oxidation of at least part of the oxide-forming layer 106 can be compensated.

Strained layers typically prevent the migration of point defects. Therefore, the strain compensating layer 104 can additionally inhibit the migration to other layers in the semiconductor device 100 of point defects that can occur as a result of oxidizing at least part of the oxide-forming layer 106. In this manner, point defects can be confined to the strain compensating layer 104 and be prevented from migrating to active light-generating portions (not shown) in the semiconductor device 100.

The additional strain compensating layer 108 may be formed to further control the strain in the completed device 100. Further, while the strain compensating layer 104 is illustrated in FIG. 1 as being grown prior to growing the oxide-forming layer 106, the layers 104 and 106 may be grown in reverse order. The order of growth depends on the characteristics desired in the finished device. Depending on the materials from which the strain compensating layers 104 and 108, and the oxide-forming layer 106 are grown, the interface 110 between the strain compensating layer 104 and the oxide-forming layer 106 will have characteristics different than the characteristics of the interface 114 between the oxide-forming layer 106 and the strain compensating layer 108. Forming the strain compensating layer 104 prior to forming the oxide-forming layer 106 will have a different effect on the completed device 100 than forming the strain compensating layer 104 after forming the oxide-forming layer 106. This is because the interface 110 between the strain compensating layer 104 and the oxide-forming layer 106 is different than the interface 114 between the oxide-forming layer 106 and the strain compensating layer 108.

For example, when growing an arsenide-based semiconductor layer adjacent a phosphide-based semiconductor layer, the interface between them typically includes a degree of intermixing of the arsenide- and phosphide-based materials when grown using metal organic chemical vapor deposition (MOCVD). This intermixing of the different materials may lead to the formation of a quaternary material at the interface. The composition and thickness of the quaternary interfacial layer is dependent upon the growth and switching sequence of the arsenide and phosphide based semiconductor layers. For example, if slightly strained Ga₁₋ₓInₓP (x˜0.5) is used to strain compensate an AlₓGa₁₋ₓAs (x>0.8) oxide layer, an intermediate AlInGaAsP layer at the InGaP/AlGaAs interface may result. In a structure where the AlGaAs layer is sandwiched between two GaInP layers, the interface between the bottom GaInP (grown prior to the AlGaAs layer) and the AlGaAs layer has a thicker AlInGaAsP layer than the interface between the AlGaAs and the top GaInP (grown after the AlGaAs layer). The reason for this is that the GaInP has a higher dissociation rate than AlGaAs at typical MOCVD growth temperatures. As a result, a portion of the phosphorus atoms in the top few monolayers may be replaced by the arsenic atoms (from the overlying AlGaAs layer) which tend to form more stable and stronger bonds with the In and Ga atoms.

An exemplary light-emitting device incorporating the strain compensating structure of the invention will now be described with reference to FIG. 2. The light emitting device shown in FIG. 2 is a VCSEL. However, other light emitting devices and non-light emitting devices may incorporate the strain compensating structure. A VCSEL is composed of an active region sandwiched between vertically-stacked mirrors, commonly known as distributed Bragg reflectors (DBRs) or Bragg mirrors. The active region typically includes quantum wells that generate the light. The quantum wells are composed of thin layers of semiconductor materials that differ in band-gap energy. To achieve the necessary reflectivity, the number of semiconductor or dielectric layers constituting each of the DBRs can be quite large. The VCSEL emits the light generated in the active region through one of the mirrors, which has a reflectivity less than that of the other of the mirrors. Light is output from a VCSEL from a relatively small area on the surface of the semiconductor, directly above or below the active region.

FIG. 2 is a schematic side view of a VCSEL 200 composed of a substrate-side distributed Bragg reflector (DBR) 230, an active layer 212, and a remote-side DBR 232, epitaxially grown, in order, on a substrate 220. In one embodiment, the remote-side DBR 232 includes strain compensating structure 112 and the semiconductor material of the substrate is single-crystal gallium arsenide. The structure shown in FIG. 2 may alternatively be grown with changes to the materials of some of the layers on an indium phosphide (InP) substrate. Further, the strain compensating structure 112 may alternatively or additionally be located in the remote-side DBR 232.

Each of DBRs 230 and 232 is composed of multiple layer pairs. Each layer pair is composed of a layer of a high refractive index material and a layer of a low refractive index material. The materials of the layers are optically transparent at the wavelength of the light generated in active region 212. Exemplary layer 234 of higher refractive index material and layer 236 of lower refractive index material constituting an exemplary layer pair of substrate-side DBR 230 are shown. Each layer has a thickness equal to one-quarter of the wavelength of the light generated in active region 212 in the material of the layer, i.e., t_{b}=λ/4n_{b}, where t_{b} is the thickness of the layer, λ is the in vacuo wavelength of the light generated in the active region and n_{b} is the refractive index of the material of the layer.

In the example shown, both DBR 230 and DBR 232 are fabricated of doped semiconductor materials and are therefore electrically conductive. In embodiments incorporating non-conductive DBRs, such DBRs may be fabricated from dielectric materials. Also in the example shown, the lower refractive index semiconductor material of layer 236 is aluminum gallium arsenide having a high aluminum content and the higher refractive index semiconductor material of layer 234 is aluminum gallium arsenide having a low aluminum content. The number of layer pairs shown in FIG. 2 is substantially reduced to simplify the drawing. In a working VCSEL, the number of layer pairs is sufficient to provide substrate-side DBR 230 and remote-side DBR 232 with a reflectivity of greater than about 99% and of about 95%, respectively, at the wavelength of the light generated in active region 212. Also, in addition to the layer pairs, each of the DBRs is composed of an additional layer of low refractive index material.

Active layer 212 is composed of quantum-well structure 214 sandwiched between the substrate-side cladding layer 216 and the remote-side cladding layer 218. The quantum-well structure 214 is composed of at least one quantum-well layer (not shown) sandwiched between respective barrier layers (not shown) of a material different from that of the quantum well layer. A dopant may be added to the materials of the active layer to enhance differential gain.

Substrate-side cladding layer 216 and the remote-side cladding layer 218 are layers of aluminum gallium arsenide (AlGaAs) with an aluminum fraction in the range from about 0.2 to about 0.8, i.e., ˜0.2≦x≦˜0.8 in AlₓGa₁₋ₓAs. A typical value of x is about 0.4. The thickness of the cladding layers and the layers of the active region are approximately one wavelength of the light generated in quantum-well structure 214 in the material of the cladding layer, i.e., t_{c}=λ/n_{c}, where t_{c} is the thickness of the cavity (cladding layers and active layer), λ is the wavelength of the light generated in the quantum-well structure and n_{c} is the effective refractive index of the AlGaAs comprising the layers of the cavity. The cladding layers are doped to have opposite conductivity types.

Generally, the semiconductor materials of the DBR adjacent to the cladding layer that is doped n-type are doped n-type and the semiconductor materials of the DBR adjacent to the cladding layer that is doped p-type are doped p-type, i.e., the materials of the DBRs have the same conductivity type as the adjacent cladding layers. At certain wavelengths of interest, the DBR fabricated of p-type materials has free carrier loss characteristics inferior to those of the DBR fabricated of n-type materials. In such a structure, a tunnel junction structure (not shown) may be incorporated to enable the semiconductor materials of both DBRs 230 and 232 to have the same conductivity type as one another, i.e., n-type, so that both DBRs have excellent optical and electrical characteristics. Alternatively, this case may be reversed if the n-type free carrier loss is inferior to the p-type free carrier loss.

Substrate-side DBR 230, active region 212 and remote-side DBR 232 collectively form an optical cavity 250 that is resonant at the wavelength of the light generated in active layer 212.

Remote-side DBR 232 includes oxide-forming layer 106, which in this example, includes a high aluminum content. The oxide-forming layer 106 is sandwiched between strain compensating layers 104 and 108, forming strain compensating structure 112. In this example, two strain compensating layers are illustrated. However, depending on the characteristics of the device, more or fewer strain compensating layers may be formed. In this example, each of the strain compensating layers 104 and 108 comprises gallium indium phosphide (Ga₁₋ₓInₓP), where x˜0.5, and the oxide-forming layer 106 comprises aluminum gallium arsenide (AlGaAs) having a high aluminum content. Typically, AlₓGa₁₋ₓl As with x˜0.96 is used for the oxide-forming layer, however, these compositions can vary. For example, the indium content in the strain compensating layers 104 and 108 can be approximately 0.45-0.55; and the aluminum content of the oxide-forming layer 106 can be approximately 0.90-0.98. Further, the strain compensating layers 104 and 108 may be grown in tension or compression, depending on the device design parameters. The strain compensating layers 104 and 108 provide strain compensation to counteract the effect of strain induced when the oxide-forming layer 106 is oxidized to form a current confinement structure.

After the layer structure composed of substrate 220, substrate-side DBR 230, active layer 212 and remote-side DBR 232 has been fabricated, part of remote-side DBR 232 and part of strain compensating structure 112 are etched away to form mesa 238. An additional current confinement structure can be formed in the mesa 238 using implantation or undercutting one of the overlying layers. For example, ions may be selectively implanted into the mesa 238 to decrease the conductivity of the mesa in all but a small, substantially central, conductive region. The conductivity of the mesa 238 remains substantially unchanged in the conductive region.

After mesa 238 has been formed, the VCSEL is heated in an oxidizing atmosphere, such as an atmosphere with a high water vapor content. The oxidizing atmosphere oxidizes the exposed areas of all the layers of AlGaAs, the oxidation progressing radially inwards from the side of the mesa. However, oxidation progresses substantially faster in the oxide-forming layer 106 than in the remaining AlGaAs layers. At the end of the oxidation process, a substantial portion of the oxide-forming layer 106 is oxidized to form a wide annular region of aluminum oxide surrounding a conductive region 248. Aluminum oxide has a substantially lower electrical conductivity than doped AlGaAs. The high-aluminum AlGaAs remains unoxidized in conductive region 248 so that the optical and electrical properties of the conductive region remain substantially unchanged. The remaining AlGaAs layers are oxidized only in a narrow annular region at their peripheries.

The area of the conductive region, e.g., 248, defined by oxidation of the oxide-forming layer is smaller than that of the mesa 238. During operation of the VCSEL 200, the laser current is confined to the conductive region 248. The laser current enters active region 212 from the conductive region. Current spreading is relatively small so that the current density is high in the active region. The very high current density lowers the threshold current of the VCSEL.

All of the layers of the VCSEL 200 are grown under thermodynamically stable conditions and are lattice matched to each other. This state is referred to as thermodynamic equilibrium. However, when the oxide-forming layer 106 is oxidized as described above, the oxidation step causes the layer 106 to be removed from a state of thermodynamic equilibrium by changing the crystal properties of the oxidized material of the layer 106 and also results in a change in the lattice parameter of the oxidized material of the layer 106 with respect to the adjoining layers. The change in the lattice parameter of the oxidized portion of the layer 106 causes point defects and lattice deformations to form and to migrate through the VCSEL structure. The point defect concentrations have different equilibrium values depending on the composition and chemical nature of the different layers that make up the crystal structure of the VCSEL 200. The composition of the strain compensating layers 104 and 108 along with the strained oxide layer determines the net strain state of the completed device after oxidation of the oxide-forming layer 106. The strain compensating layers 104 and 108 reduce the number of point defects that occur as the result of the oxidation by reducing the net strain after the oxidation. The strain compensating layers 104 and 106 subject the oxide-forming layer 106 to strain so that the oxide layer, after it is formed, is under less strain than it would be absent the strain compensating layers 104 and 108. As a result, the strain compensating layers 104 and 108 reduce the number of point defects resulting from the oxidation and additionally limit the migration of those point defects that are produced.

To make a top emitting device, a substrate-side contact layer 240, composed of at least one layer of metal, is deposited either on the surface of the substrate 220 or on top of substrate-side DBR 230 by etching a mesa. A remote-side contact layer 242 is deposited on the exposed surface of remote-side DBR 232 and is patterned to define a light exit port 244. The light exit port 244 is radially aligned with conductive region 248. The remote-side contact layer 242 is composed of at least one layer of metal, and may additionally include at least one layer of p-type semiconductor material having a high dopant concentration to reduce the contact resistance between the metal layer and remote-side DBR 232. As mentioned before, the VCSEL may be fabricated n-type on the top and p-type on the bottom. Further, the light exit port may be fabricated in the bottom contact 240 to make a bottom emitting device. Alternatively, metal can be formed on top of the bottom DBR 230 after etching a mesa to eliminate the need for a light opening port since, in such a configuration, the metal is no longer in the light path.

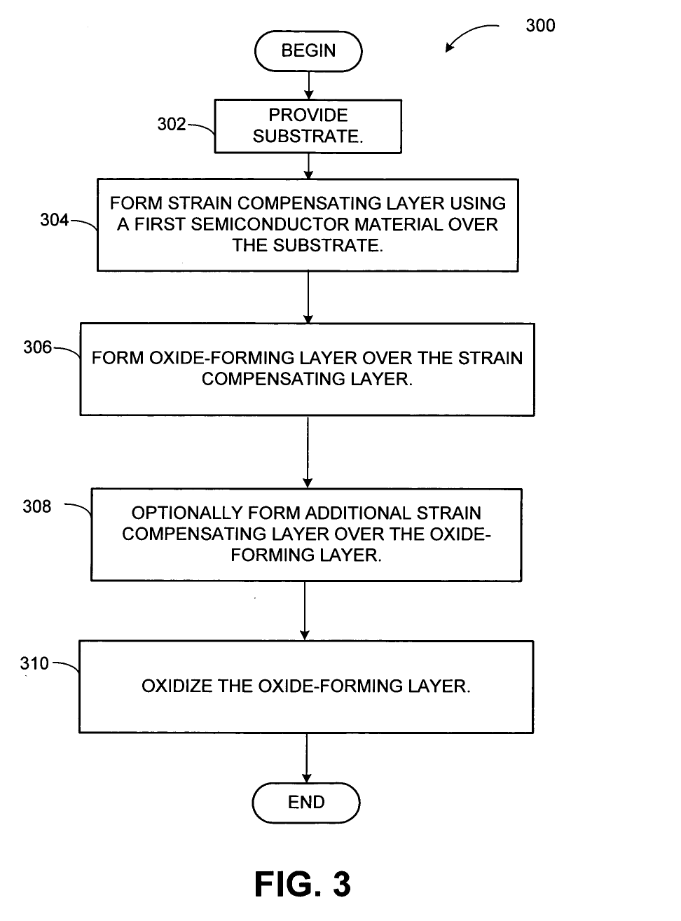

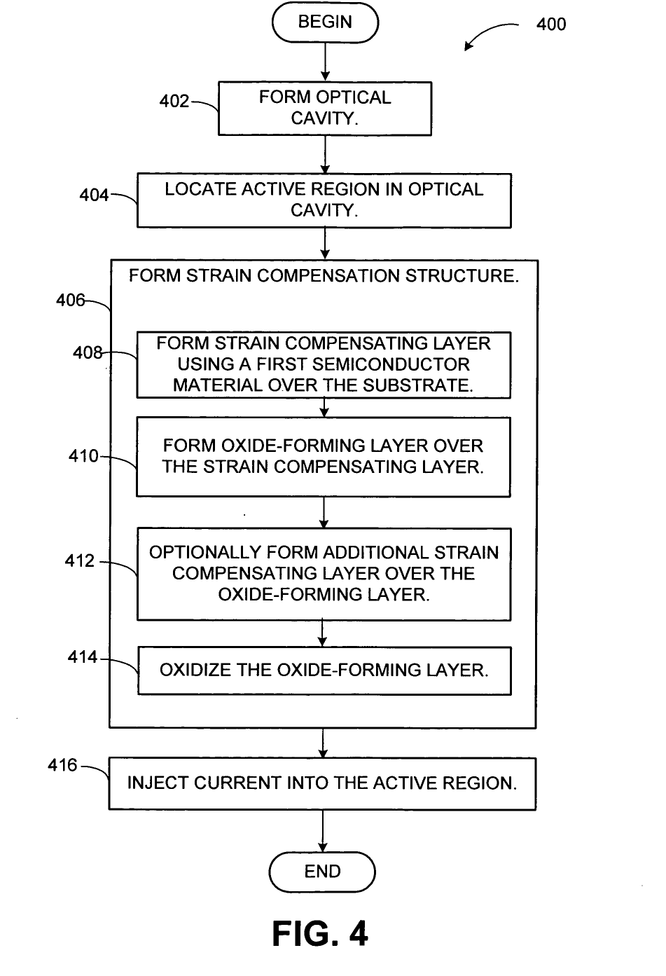

An example of a method according to the invention for making a strain compensating structure and for generating light will now be described below with reference to FIGS. 3 and 4. In the descriptions of the methods, it should be understood that although particular stages in the processes are described, alternative implementations are feasible. Moreover, some processes may be executed in an order different from that shown. For examples, processes may be executed substantially concurrently or in reverse order.

FIG. 3 illustrates a method 300 according to the invention for making a strain compensating structure. In block 302 a substrate is provided. In block 304, a strain compensating layer of a first semiconductor material is formed over the substrate. This can be accomplished by depositing a layer of the first semiconductor material over or on the substrate.

In block 306, an oxide-forming layer of a second semiconductor material is formed juxtaposed with the strain compensating layer. The strain compensating layer and the oxide-forming layer collectively form a strain compensating structure. The first semiconductor material of the strain compensating layer can be, for example, gallium indium phosphide and the second semiconductor material of the oxide-forming layer can be, for example, aluminum gallium arsenide having a high aluminum fraction of about 0.90-0.98.

The strain compensating layer can be formed strained in either compression or tension to compensate for the change in the lattice parameter that occurs due to oxidation of at least part of the oxide-forming layer.

In block 308 an additional strain compensating layer is optionally formed over the oxide-forming layer. The additional strain compensating layer may be formed using the first semiconductor material from which the first strain compensating layer is formed. The additional strain compensating layer may be formed using either the same composition as or a different composition from that of the first strain compensating layer.

In block 310 at least part of the oxide-forming layer is oxidized, causing the lattice parameter of the oxide-forming layer to change. The strain compensating layer(s) provides either tensile or compressive strain so that after oxidation of the oxide-forming layer, the strain compensating layer(s) compensates for the change in the lattice parameter of the oxide-forming layer and also acts as a blocking layer for point defects.

FIG. 4 illustrates a method 400 according to the invention for generating light. In block 402, an optical cavity is formed. In block 404, an active region is located in the optical cavity. In block 406, a strain compensating structure is formed. Block 406 includes blocks 408, 410, 412 and 414. In block 408, a strain compensating layer of a first semiconductor material is formed.

In block 410, an oxide-forming layer is formed over the strain compensating layer. In block 412, an additional strain compensating layer is formed over the oxide-forming layer. In block 414, at least part of the oxide-forming layer is oxidized to form a current confinement structure.

In block 416, current is injected through the current confinement structure into the active region to cause the active region to generate light.

This disclosure describes the invention in detail using illustrative embodiments. However, it is to be understood that the invention defined by the appended claims is not limited to the precise embodiments described.

1. A light-emitting device, comprising:
an active region configured to generate light in response to injected charge; and
a current confinement structure located to direct charge into the active region and including a strain compensating layer adjacent an oxide-forming layer.

2. The light-emitting device of claim 1, in which the current confinement structure comprises an additional strain compensating layer adjacent the oxide-forming layer, where the oxide-forming layer is sandwiched between the strain compensating layers.

3. The light-emitting device of claim 1, in which the strain compensating layer comprises gallium, indium and phosphorus.

4. The light-emitting device of claim 1, in which the oxide-forming layer comprises aluminum, gallium and arsenic.

5. The light-emitting device of claim 1, in which the strain compensating layer consists essentially of Ga₁₋ₓInₓP, where x≦0.5.

6. The light-emitting device of claim 1, in which the oxide-forming layer consists essentially of AlₓGa₁₋ₓAs, where x≧0.96.

7. The light-emitting device of claim 1, in which:
the strain compensating layer consists essentially of gallium indium phosphide GaInP; and
the oxide-forming layer consists essentially of aluminum gallium arsenide AlGaAs.

8. The light-emitting device of claim 7, in which:
the strain compensating layer consists essentially of gallium indium phosphide Ga₁₋ₓInₓP in which x≦0. 5; and
the oxide-forming layer essentially of aluminum gallium arsenide AlₓGa₁₋ₓAs in which x≧0.96.

9. The light-emitting device of claim 1, structured to generate light having a wavelength between 620 nm and 1650 nm.

10. A method of making a strain compensating structure, the method comprising:
providing a substrate;
forming over the substrate a strain compensating layer of a first semiconductor material;
forming an oxide-forming layer of a second semiconductor material juxtaposed with the strain compensating layer to form the strain compensating structure; and
oxidizing at least part of the oxide-forming layer.

11. The method of claim 10, in which:
the first semiconductor material comprises indium, gallium and phosphorus; and
the second semiconductor material comprises aluminum, gallium and arsenide.

12. The method of claim 1 1, further comprising:
forming the strain compensating layer using Ga₁₋ₓInₓP, where x≦0.5; and
forming the oxide layer using AlₓGa₁₋ₓAs, where x≧0.96.

13. A method for generating light, the method comprising:
forming an optical cavity;
locating an active region in the optical cavity, the active region configured to generate light in response to injected current;
forming a current confinement structure located to direct current into the active region, including:
forming a strain compensating layer of a first semiconductor material including gallium (Ga), indium (In) and phosphorus (P);
forming an oxide-forming layer of a second semiconductor material including aluminum (Al) gallium (Ga) and arsenic (As);
oxidizing at least part of the oxide-forming layer; and
injecting current into the active region using the current confinement structure.

14. The method of claim 13, in which the active region is configured to generate light having a wavelength between 620 nm and 1650 nm.

15. A strain compensating structure, comprising:
a strain compensating layer of a first semiconductor material including gallium (Ga), indium (In) and phosphorus (P); and
an oxide-forming layer of a second semiconductor material including aluminum (Al) gallium (Ga) and arsenic (As) juxtaposed with the strain compensating layer.

16. The strain compensating structure of claim 15, in which the first semiconductor material consists essentially of gallium indium phosphide Ga₁₋ₓInₓ P in which x≦0.5.

17. The strain compensating structure of claim 15, in which the second semiconductor material consists essentially of aluminum gallium arsenide AlₓGa₁₋ₓAs in which x≧0.96.

18. The strain compensating structure of claim 15, in which:
the first semiconductor material consists essentially of gallium indium phosphide (GaInP); and
the second semiconductor material consists essentially of aluminum gallium arsenide (AlGaAs).

19. The strain compensating structure of claim 18, in which:
the first semiconductor material consists essentially of gallium indium phosphide Ga₁₋ₓInₓ P in which x≦0.5; and
the second semiconductor material essentially of aluminum gallium arsenide AlₓGa₁₋ₓAs in which x≧0.96.
